(19) United States
(12) Patent Application Publication
(10) Pub. No.: US 2024/0222461 A1
(43) Pub. Date: Jul. 4, 2024

(54) BEOL CONTACT METALS FOR 2D TRANSISTORS

(71) Applicant: Intel Corporation, Santa Clara, CA (US)

(72) Inventors: Ande Kitamura, Portland, OR (US); Carl H. Naylor, Portland, OR (US); Kevin O'Brien, Portland, OR (US); Kirby Maxey, Hillsboro, OR (US); Chelsey Dorow, Portland, OR (US); Ashish Verma Penumatcha, Beaverton, OR (US); Scott B. Clendenning, Portland, OR (US); Uygar Avci, Portland, OR (US); Matthew Metz, Portland, OR (US); Chia-Ching Lin, Portland, OR (US); Sudarat Lee, Hillsboro, OR (US); Mahmut Sami Kavrik, Eugene, OR (US); Carly Rogan, North Plains, OR (US); Paul Gutwin, Williston, VT (US)

(73) Assignee: Intel Corporation, Santa Clara, CA (US)

(21) Appl. No.: 18/091,201

(22) Filed: Dec. 29, 2022

(51) Int. Cl. H01L 29/45; H01L 21/02; H01L 21/443; H01L 23/528; H01L 29/06; H01L 29/24; H01L 29/417; H01L 29/423; H01L 29/66; H01L 29/76; H01L 29/775

(52) U.S. Cl. CPC H01L 29/45; H01L 21/02568; H01L 21/443; H01L 23/5286; H01L 29/0673; H01L 29/24; H01L 29/41733; H01L 29/42392; H01L 29/66969; H01L 29/7606; H01L 29/775

(57) ABSTRACT

A transistor in an integrated circuit (IC) die includes source and drain terminals having a bulk material enclosed by a liner material. A nanoribbon channel region couples the source and drain terminals. The nanoribbon may include a transition metal and a chalcogen. The liner material may contact ends and upper and lower surfaces of the nanoribbon. The transistor may be in an interconnect layer. The source and drain terminals may be formed by conformally depositing the liner material over the ends of the nanoribbon and in voids opened in the IC die.

### BACKGROUND

Transistors made in the back end of line (BEOL) and, for example, deployed in interconnect layers offer great possibility for improving the overall performance of integrated circuit dies. However, many transistor channel materials are not suited for manufacture in the BEOL. While some materials offer great promise as BEOL channel materials, forming good electrical contacts with these materials poses new problems. High contact resistance may limit device performance.

Methods and materials are needed to make low-resistance contacts with new channel materials.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1 illustrates a cross-sectional profile view of a transistor structure in an integrated circuit (IC) die, including conformal liner materials of source and drain terminals contacting nanoribbons;

FIGS. 2A and 2B illustrate cross-sectional profile views of a transistor structure in an IC die, including conformal liner materials of source and drain terminals contacting nanoribbons;

FIG. 3 illustrates a cross-sectional profile view of an IC device having high-performing two-dimensional (2D) CMOS devices in front-side or back-side interconnect layers;

FIGS. 4A and 4B illustrate cross-sectional profile views of a transistor structure in an IC die, including conformal liner materials of source and drain terminals contacting nanoribbons;

FIG. 5 illustrates a cross-sectional profile view of a transistor structure in an IC die, including conformal liner materials of source and drain terminals contacting nanoribbons and split or multiple gate structures coupled to nanoribbons;

FIG. 6 illustrates various processes or methods for forming transistors with 2D channel regions coupled to source and drain terminals by conformal contact metals;

FIGS. 7A, 7B, 7C, 7D, 7E, 7F, 7G, 7H, 7I, 7J, 7K, and 7L illustrate cross-sectional profile views of a transistor structure in an IC die, including conformal liner materials of source and drain terminals contacting nanoribbons, at various stages of manufacture;

FIG. 8 illustrates a diagram of an example data server machine employing an IC device having 2D nanoribbon channel regions in interconnect layers; and

FIG. 9 is a block diagram of an example computing device, all in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure. The term “aligned” (i.e., vertically or laterally) indicates at least a portion of the components are aligned in the pertinent direction while “fully aligned” indicates an entirety of the components are aligned in the pertinent direction.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking, or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed for forming transistors having channel regions with two-dimensional (2D) materials and conformal contact metals for coupling 2D channel regions to source and drain terminals. Channel regions of 2D materials, e.g., nanoribbons, may be formed in a layer having a thickness of only an atomic or molecular monolayer, which may be a thickness of less than 1 nm. Semiconductor 2D materials may have high charge-carrier mobilities and on/off current ratios, but forming low-resistance contacts may provide challenges. Contacting ends of 2D nanoribbons with a conformal contact metal may improve device performance by enhancing contacts between channel regions and source and drain terminals. Extending ends of nanoribbon channel regions into those terminals may further enhance contact, e.g., by increasing the contact area of the coupled structures.

A nanoribbon may be a crystalline monolayer of a transition metal dichalcogenide (TMD), a notable class of 2D materials. Conformal contact metals may contact an end of a TMD nanoribbon and may advantageously additionally contact top, bottom, and side portions of a nanoribbon. Conformal contact may be used with back-gated nanoribbons, on end and top (and side) surfaces. Various conformal contact metals are available. Although the term may also describe a material's deposition method, the term “conformal” may refer to a material's structure, meaning that the material “conforms” to the shape of, or has the same shape as, an abutting structure. As deployed in source and drain terminals, a conformal contact metal may be a liner material with a remainder of a terminal being a bulk or fill metal. Although called a contact “metal,” a liner material may be any conductive material making up a surface of a source or drain terminal. Some useful liner materials are metals, some are 2D materials, such as graphene or a TMD (e.g., doped or in a metallic or 1T phase), and other materials are other compounds or composites combining chalcogens and metals.

Source and drain terminals may be formed by opening up voids in an insulator or sacrificial layer adjacent a nanoribbon and conformally depositing a liner material on the surfaces of the void. A bulk metal may fill the void within the liner material conformally on the surfaces of the void. Such a process for making source and drain terminals may be compatible with back end of line (BEOL) flows, for example, in interconnect, e.g., metallization, layers over a device layer. BEOL embodiments may include front- and back-side structures.

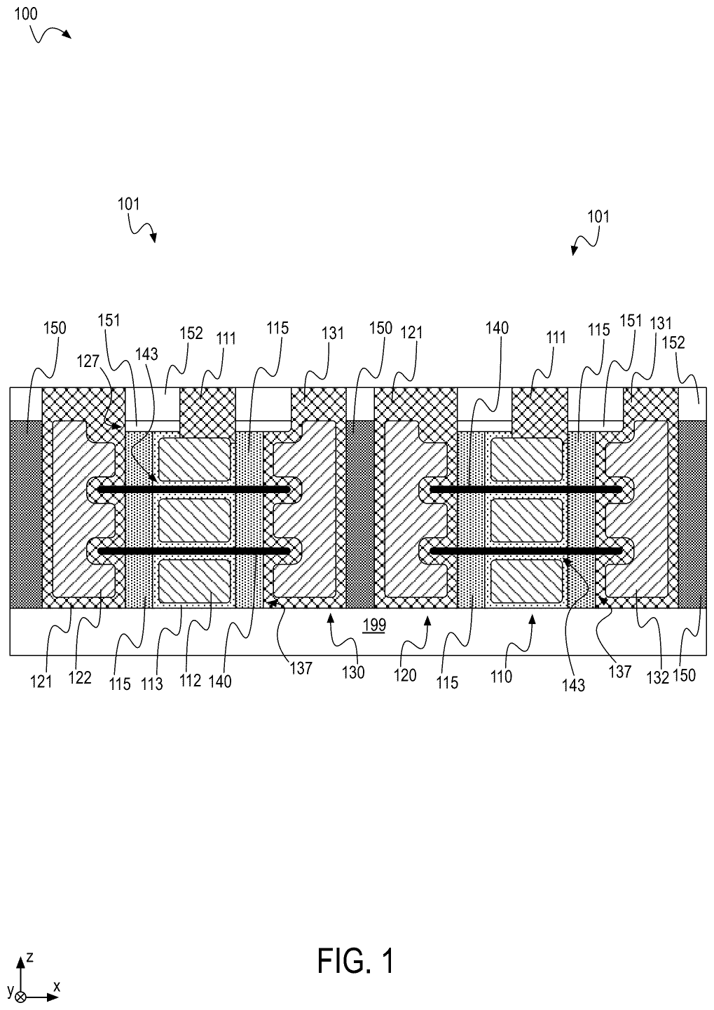

FIG. 1 illustrates a cross-sectional profile view of a transistor structure 101 in an integrated circuit (IC) die 100, including conformal liner materials 121, 131 of source and drain terminals 120, 130 contacting nanoribbons 140. Transistor structure 101 is over substrate 199 and includes source terminal 120 and drain terminal 130 within IC die 100. Transistor structure 101 may be in a traditional device layer, e.g., with metallization or interconnect layers built up over transistor structure 101. Transistor structure 101 may be in a metallization or interconnect layer built up over a device layer (e.g., in a metallization or interconnect layer over multiple metallization or interconnect layer over a device layer). Source terminal 120 includes liner material 121 and a bulk material 122. Drain terminal 130 includes liner material 131 and a bulk material 132. Although structures may be referred to as a source or drain, e.g., terminal, in some examples, these labels are not restrictive and may be reversed in this and other embodiments.

Nanoribbon 140 is between and coupled to source and drain terminals 120, 130. At least a portion of each of liner materials 121, 131 is between nanoribbon 140 and bulk materials 122, 132. A gate electrode 112 is coupled to nanoribbon 140 by a gate insulator layer 113. Gate insulator layer 113 is coupled to a channel region 143 of nanoribbon 140. Gate insulator layer 113 is between nanoribbon 140 and gate electrode 112. Gate contact 111 is coupled to gate electrode 112. Spacers 115 are between a gate structure 110 and both of source and drain terminals 120, 130, within transistor structure 101. Spacers 150 are between adjacent transistor structures 101. Various other insulators 151, 152 insulate various structures from other various structures, potentially including any structures over or adjacent transistor structure 101.

Nanoribbon 140 is of a 2D material. In some embodiments, nanoribbon 140 is a TMD monolayer, including a transition metal (such as tungsten or molybdenum) and a chalcogen (such as sulfur or selenium). In some such embodiments, nanoribbon 140 is a crystalline monolayer of tungsten disulfide (WS₂), tungsten diselenide (WSe₂), molybdenum disulfide (MoS₂), or molybdenum diselenide (MoSe₂). The entire nanoribbon 140 may be a molecular monolayer having metal atoms with atomic planes of chalcogens above and below along the entirety of its length.

Liner materials 121, 131 make up the sidewalls 127, 137 of source and drain terminals 120, 130, but are also conformal to multiple ends of multiple nanoribbons 140. Nanoribbons 140 extend laterally beyond spacers 115 and sidewalls 127, 137 of source and drain terminals 120, 130. Liner materials 121, 131 are conformal to the ends of nanoribbons 140 that extend into the extent of source and drain terminals 120, 130. Liner materials 121, 131 directly contact the ends of multiple nanoribbons 140. Liner materials 121, 131 directly contact the upper and lower surfaces of multiple nanoribbons 140. Liner materials 121, 131 also directly contact substrate 199 at the lower surfaces of source and drain terminals 120, 130. Liner materials 121, 131 directly contact spacers 115, 150 at sidewalls 127, 137 of source and drain terminals 120, 130. Liner materials 121, 131 directly contact spacers 115, 150 at sidewalls 127, 137 of source and drain terminals 120, 130. Liner materials 121, 131 directly contact insulators 151, 152 high on sidewalls 127, 137 of source and drain terminals 120, 130.

Liner materials 121, 131 may be any suitable material, e.g., sufficiently conductive and capable of conforming to adjoining structures. Some liner materials 121, 131 may have a propensity for forming bonds with the 2D materials of nanoribbons 140, e.g., TMD. Liner materials 121, 131 may include a metal. In some embodiments, liner materials 121, 131 include at least one of antimony, gold, silver, nickel, titanium, ruthenium, tin, bismuth, aluminum, germanium, tantalum, palladium, platinum, iridium, tungsten, rhodium, or molybdenum. Metals may advantageously have a suitable work function for a given transistor type, e.g., N- or P-type. For example, in some N-type embodiments, liner materials 121, 131 include at least one of antimony, gold, silver, nickel, titanium, ruthenium, tin, bismuth, aluminum, germanium, or tantalum. In some P-type embodiments, liner materials 121, 131 include at least one of palladium, platinum, ruthenium, gold, iridium, tungsten, nickel, rhodium, or molybdenum. Liner materials 121, 131 may be a compound, 2D or otherwise, of a metal and a chalcogen. In some embodiments, liner materials 121, 131 include one of rhenium, cobalt, or nickel, and one of sulfur or selenium (e.g., ReₓSy, ReₓSe_{y}, CoₓS_{y}, CoₓSe_{y}, NiₓS_{y}, or NiₓSe_{y}).

Liner materials 121, 131 may be a 2D material, which may provide a conductive surface of source or drain terminals 120, 130 while minimizing a thickness of liner materials 121, 131. In some embodiments, liner materials 121, 131 include graphene or a TMD. The TMD may include both, one of, or neither of a transition metal and a chalcogen of a TMD nanoribbon 140. In some embodiments, the TMD of liner materials 121, 131 includes a dopant, e.g., to increase conductivity. TMD of the same or similar composition may have differing electrical characteristics due to having differing crystalline structures. For example, a TMD in a 2H crystalline phase (e.g., a molecular monolayer with vertically aligned chalcogen atoms) may be a semiconductor, while a TMD with the same composition but in a 1T crystalline phase (e.g., a molecular monolayer with vertically unaligned chalcogen atoms) may be metallic (or semimetallic). In some embodiments, the TMD of liner materials 121, 131 is in a metallic crystalline phase. In some embodiments, the TMD of liner materials 121, 131 is in a 1T crystalline phase. Other materials may be used. In some embodiments, liner materials 121, 131 having TMD in a metallic or 1T crystalline phase may include TMD in a semiconductor or 2H crystalline phase, for example, as residue from a conversion from one crystalline structure to the other. Some liner materials 121, 131 include a TMD monolayer having two chalcogen atoms for every metal atom, but with a different chalcogen above than below the metal atoms. In some embodiments, an atomic plane of a metal is between an atomic plane of sulfur and an atomic plane of selenium (e.g., a molecular monolayer of MoSSe or WSSe).

Liner materials 121, 131 enclose bulk materials 122, 132 of source and drain terminals 120, 130. Bulk materials 122, 132 may be metals of sufficient conductivity, e.g., copper, tungsten, cobalt, or ruthenium. Other materials may be suitable. These or other bulk materials 122, 132 may be selected for their compatibility with a given liner material 121, 131 and suitability for interconnect or other metallization embodiments. The structure of source and drain terminals 120, 130 (including a conformal structure of liner materials 121, 131 enclosing bulk materials 122, 132) may enable the deployment of transistor structure 101 in a metallization or interconnect layer over a device layer.

Gate insulator layer 113 is coupled to nanoribbons 140. Gate insulator layer 113 is part of gate structure 110 and electrically insulates, e.g., gate electrode 112 from nanoribbons 140. Gate insulator layer 113 allows for electrostatic control, e.g., by gate electrode 112, of channel region 143. Gate insulator layer 113 may be of or include a high-k (e.g., high permittivity) dielectric material, which may enable good electrostatic control while minimizing gate leakage currents. Gate insulator layer 113 may have one or more sublayers. The high-k dielectric material may include hafnium oxide, hafnium silicon oxide, lanthanum oxide, lanthanum aluminum oxide, zirconium oxide, zirconium silicon oxide, tantalum oxide, titanium oxide, barium titanium oxide, strontium titanium oxide, yttrium oxide, aluminum oxide, etc. Other dielectric material may be used, such as a silicon oxide (e.g., silicon dioxide, SiO2).

Gate electrode 112 is on gate insulator layer 113 and may include of at least one of a p-type work function metal or an n-type work function metal, depending on whether the transistor is a PMOS or an NMOS transistor. In some embodiments, gate electrode 112 includes two or more metal layers, where one or more metal layers are work function metal layers and at least one metal layer is a fill metal layer. For a PMOS transistor, metals that may be used for the gate electrode include, but are not limited to, ruthenium, palladium, platinum, cobalt, nickel, and conductive metal oxides, e.g., ruthenium oxide. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, or tantalum carbide. Gate electrode 112 is coupled to gate contact 111, which may be of the same liner materials 121, 131 of source and drain terminals 120, 130.

Spacer 115 insulates, e.g., gate electrode 112 from source and drain terminals 120, 130. Spacer 115 may be of a low-k dielectric material. Similarly, spacer 150 may be between transistor structures 101 and, for example, insulates source and drain terminals 120, 130 of different transistor structures 101. Spacer 150 may be of a low-k dielectric material.

Substrate 199 may include any suitable material or materials. In some examples, the substrate may include monocrystalline silicon (including silicon on insulator (SOI)), polycrystalline silicon, germanium, silicon germanium, a III-V alloy material (e.g., gallium arsenide), a silicon carbide (e.g., SiC), a sapphire (e.g., Al₂O₃), or any combination thereof. Substrate 199 may also include semiconductor materials, metals, dielectrics, dopants, and other materials commonly found in semiconductor substrates. Transistor structures 101 may be over a dielectric layer over other materials.

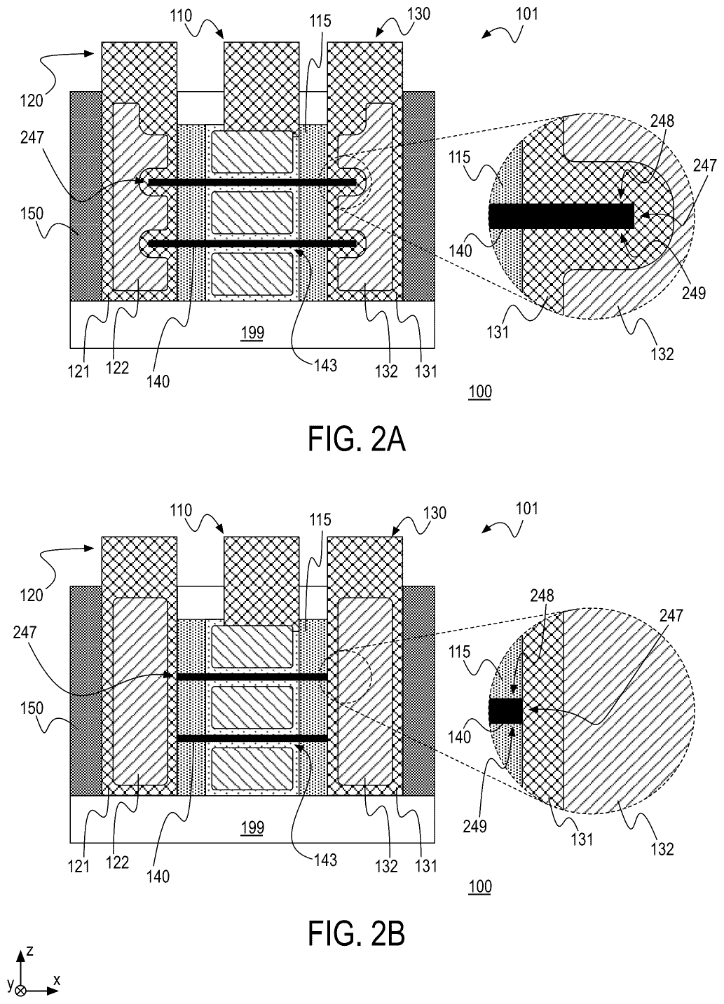

FIGS. 2A and 2B illustrate cross-sectional profile views of transistor structure 101 in IC die 100, including conformal liner materials 121, 131 of source and drain terminals 120, 130 contacting nanoribbons 140, in accordance with some embodiments. FIG. 2A shows liner material 131 of drain terminal 130 directly contacting ends 247 of nanoribbons 140. Liner material 131 also directly contacts upper surfaces 248 and lower surfaces 249 of nanoribbons 140. Liner material 121 similarly directly contacts ends 247, upper surfaces 248, and lower surfaces 249 of nanoribbons 140 at source terminal 120. Liner materials 121, 131 are conformal to spacers 115, 150 and to ends 247 and upper and lower surfaces 248, 249 of nanoribbons 140 that extend into the extent of source and drain terminals 120, 130. Liner materials 121, 131 directly contact the ends of multiple nanoribbons 140.

FIG. 2B shows liner material 131 of drain terminal 130 directly contacting ends 247 of nanoribbons 140. In some embodiments, liner material 131 does not contact upper surfaces 248 and lower surfaces 249 of nanoribbons 140. Similarly, in some embodiments, liner material 121 directly contacts ends 247 and not upper and lower surfaces 248, 249 of nanoribbons 140 at source terminal 120. Liner materials 121, 131 are conformal to spacers 115, 150 and to the ends of nanoribbons 140. Nanoribbons 140 extend only to sidewalls of spacers 115 and do not extend into source and drain terminals 120, 130, so liner materials 121, 131 do not contact upper and lower surfaces 248, 249 of nanoribbons 140.

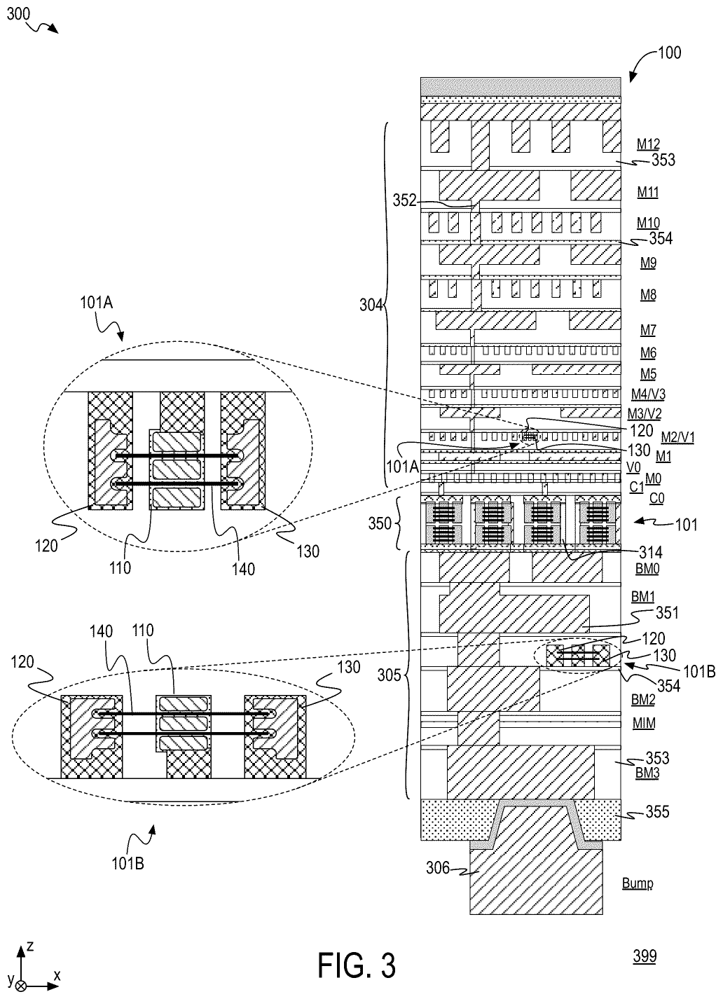

FIG. 3 illustrates a cross-sectional view of an IC device 300 having high-performing 2D CMOS devices in front-side and back-side interconnect layers 304, 305, in accordance with some embodiments. In the example of IC device 300, IC die 100 includes transistor structures 101 having channel regions in nanoribbons 140, which couple source and drain terminals 120, 130 and are coupled to gate structure 110. Notably, some of transistor structures 101 and source and drain terminals 120, 130 in IC device 300 are deployed in front-side and back-side interconnect layers 304, 305. For example, transistor structure 101A is deployed in front-side interconnect layers 304, and transistor structure 101B is deployed in back-side interconnect layers 305. Transistor structures 101A, 101B are shown within front-side and back-side interconnect layers 304, 305 and are also shown magnified, e.g., for clarity.

In FIG. 3, IC device 300 includes an IC die 100, which is a monolithic IC with 2D CMOS devices as described above, including transistor structures 101, front-side metallization layers 304 (or front-side interconnect layers), and optional back-side metallization layers 305 (or back-side interconnect layers). IC device 300 includes a lateral surface along the x-y plane that may be defined or taken at any vertical position of IC device 300. The lateral surface of the x-y plane is orthogonal to a vertical or build-up dimension as defined by the z-axis. As shown, transistor structures 101 are non-planar transistors, some of which are embedded within a device layer 350. Each of transistor structures 101 include channel regions within nanoribbons, gate structures, and gate contacts. Each of transistor structures 101 also include source and drain structures, and source and drain contacts. In some embodiments, front-side metallization layers 304 provide signal routing to device layer 350 and back-side metallization layers 305 provide power delivery, as enabled by through-contacts 314, to device layer 350. IC device 300 may also be deployed without back-side metallization layers 305 shown in FIG. 3. In such embodiments, signal routing and power are provided to device layer 350 via front-side metallization layers 304. However, use of back-side metallization layers 305 may offer advantages.

Interconnectivity of transistor structures 101 (and other transistors, etc.), signal routing to and from device layer 350, etc., power delivery to device layer 350, etc., and routing to an outside device (not shown), is provided by front-side metallization layers 304, optional back-side metallization layers 305, and package-level interconnects 306. In the example of FIG. 3, package-level interconnects 306 are provided on or over a back-side of IC die 100 as bumps over a passivation layer 355, and IC device 300 is coupled to host component 399 (and coupled to signal routing to, power delivery from a power supply, etc.) by package-level interconnects 306. However, package-level interconnects 306 may be provided using any suitable interconnect structures such as bond pads, solder bumps, etc. Furthermore, in some embodiments, package-level interconnects 306 are provided on or over a front-side of IC die 100 (i.e., over front-side metallization layers 304).

As used herein, the term “metallization layer” or “interconnect layer” describes layers primarily with interconnections or wires that provide electrical routing, generally formed of metal or other electrically and thermally conductive material. Adjacent metallization layers may be formed of different materials and by different methods. Metallization and interconnect layers may generally be over a device layer, e.g., device layer 350, including in a stack of multiple interconnect layers over a device layer. A device layer may include metallization and other interconnect features, but a device layer may be the layer, or one of the two or few layers, containing the all or the majority of the transistors in an IC die. A device layer may be at or adjacent a base from which both the front- and back-sides are built up (e.g., first in one direction and then the opposite). While transistors are often not deployed in layers meant primarily for interconnections, transistor structures 101 may be deployed in metallization layers over device layers, as described. Adjacent metallization layers, such as metallization interconnects 351, are interconnected by vias, such as vias 352, that may be characterized as part of the metallization layers or between the metallization layers. As shown, in some embodiments, front-side metallization layers 304 are formed over and immediately adjacent transistor structures 101. The back-side is then the opposite side, which may be exposed during processing by attaching the front-side to a carrier wafer and exposing the back-side (e.g., by back-side grind or etch operations) as known in the art.

In the illustrated example, front-side metallization layers 304 include M0, V0, M1, M2/V1, M3/V2, M4/V3, and M4-M12. However, front-side metallization layers 304 may include any number of metallization layers such as eight or more metallization layers. Similarly, back-side metallization layers 305 include BM0, BM1, BM2, and BM3. However, back-side metallization layers 305 may include any number of metallization layers such as two to five metallization layers. Front-side metallization layers 304 and back-side metallization layers 305 are embedded within dielectric materials 353, 354. Furthermore, optional metal-insulator-metal (MIM) devices such as diode devices may be provided within back-side metallization layers 305. Other devices such as capacitive memory devices may be provided within front-side metallization layers 304 and/or back-side metallization layers 305.

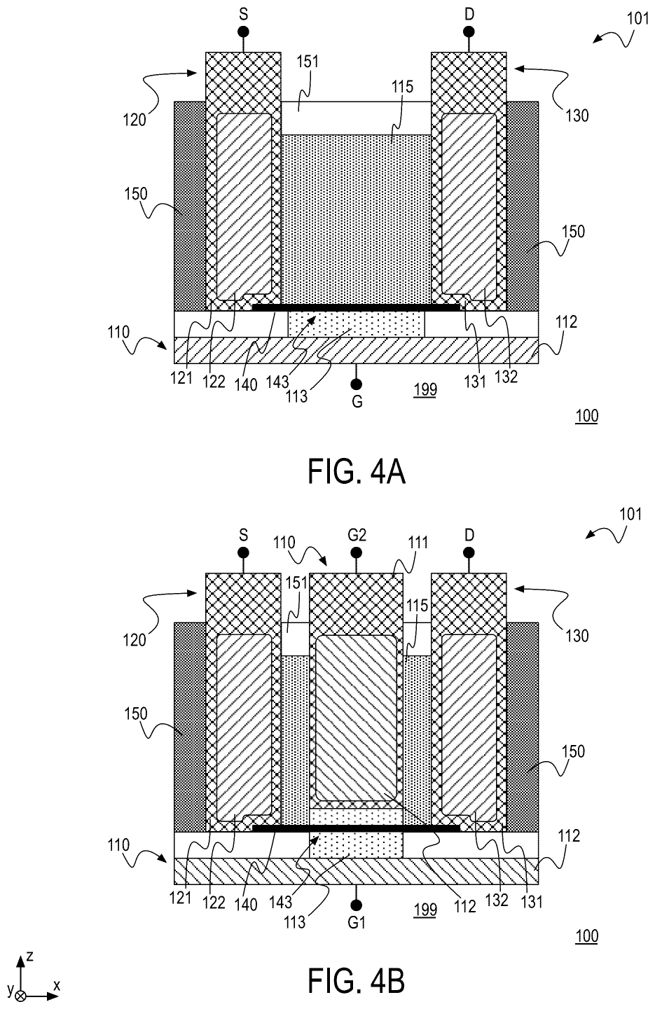

FIGS. 4A and 4B illustrate cross-sectional profile views of transistor structure 101 in IC die 100, including conformal liner materials 121, 131 of source and drain terminals 120, 130 contacting nanoribbons 140, in accordance with some embodiments. FIG. 4A shows a back-gated transistor structure 101 with a single channel region 143 in nanoribbon 140. Gate insulator layer 113 is over a layer of the material of gate electrode 112. Nanoribbon 140 is over gate insulator layer 113. Source and drain terminals 120, 130 are over nanoribbon 140. Liner materials 121, 131 both each directly contact an end and an upper surface of nanoribbon 140. In some embodiments, liner materials 121, 131 both each directly contact an upper surface of nanoribbon 140, but not an end of nanoribbon 140, e.g., when an upper surface of nanoribbon 140 is coplanar with a lower surface of source and drain terminals 120, 130. Spacer 115, which may be of a low-k dielectric, is over nanoribbon 140.

FIG. 4B illustrates a similar back-gated transistor structure 101 with a single channel region 143 in nanoribbon 140, but with an additional gate electrode 112 (and gate contact 111), which may be independently controlled. In the case of lower gate electrode 112 (at G1), gate insulator layer 113 is over a layer of the material of gate electrode 112. Nanoribbon 140 is over gate insulator layer 113. Source and drain terminals 120, 130 are over nanoribbon 140. Liner materials 121, 131 both each directly contact an end and an upper surface of nanoribbon 140. In some embodiments, liner materials 121, 131 both each directly contact an upper surface of nanoribbon 140, but not an end of nanoribbon 140, e.g., when an upper surface of nanoribbon 140 is coplanar with a lower surface of source and drain terminals 120, 130. Additionally, an upper gate electrode 112 (at G2) is over another gate insulator layer 113, which is over nanoribbon 140. Gates G1, G2 may be independently controlled or coupled and controlled together.

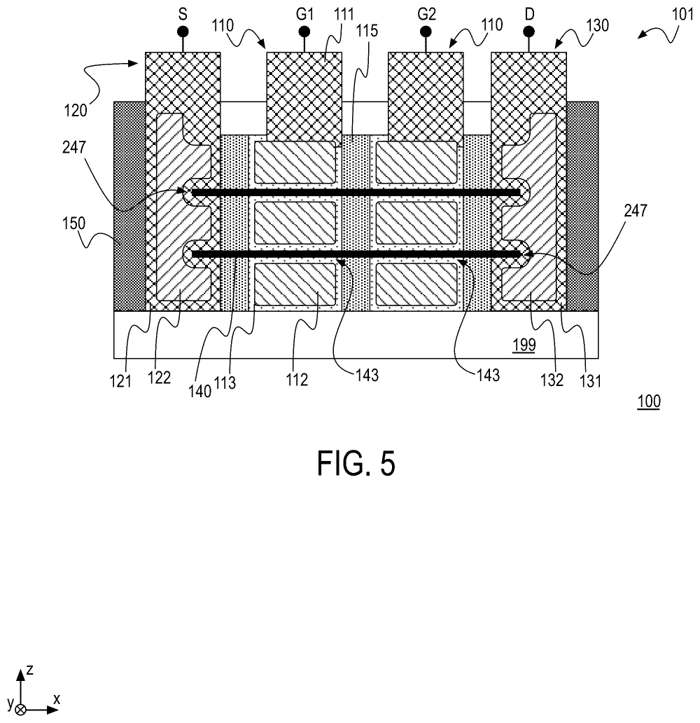

FIG. 5 illustrates a cross-sectional profile view of transistor structure 101 in IC die 100, including conformal liner materials 121, 131 of source and drain terminals 120, 130 contacting nanoribbons 140 and split or multiple gate structures 110 coupled to nanoribbons 140, in accordance with some embodiments. Transistor structure 101 may be similar to transistor structures 101 previously described, e.g., in FIG. 1 or 2A, but with multiple gate structures 110, which may be controlled independently (at G1 and G2).

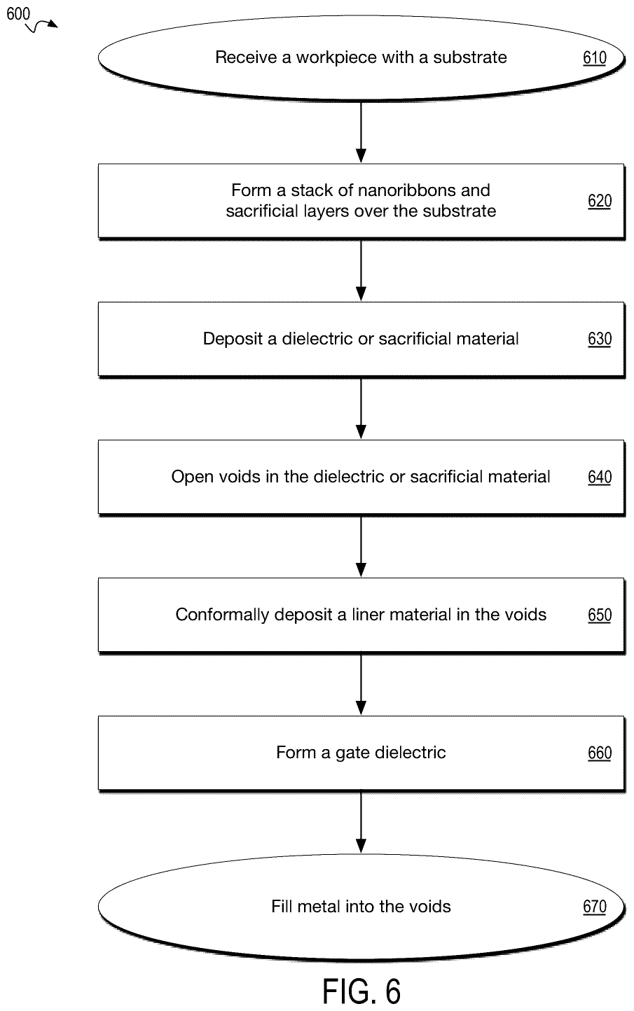

FIG. 6 illustrates various processes or methods 600 for forming transistors with 2D channel regions coupled to source and drain terminals by conformal contact metals, in accordance with some embodiments. FIG. 6 shows methods 600 that includes operations 610-670. Some operations shown in FIG. 6 may overlap with other operations. FIG. 6 shows an example sequence, but the operations can be done in other sequences as well, and some operations may be omitted. Some operations can also be performed multiple times before other operations are performed. Optional operations will be described. Methods 600 generally entail forming transistor channel regions (and other structures) and contacting the ends of the channel regions with a conformal contact metal.

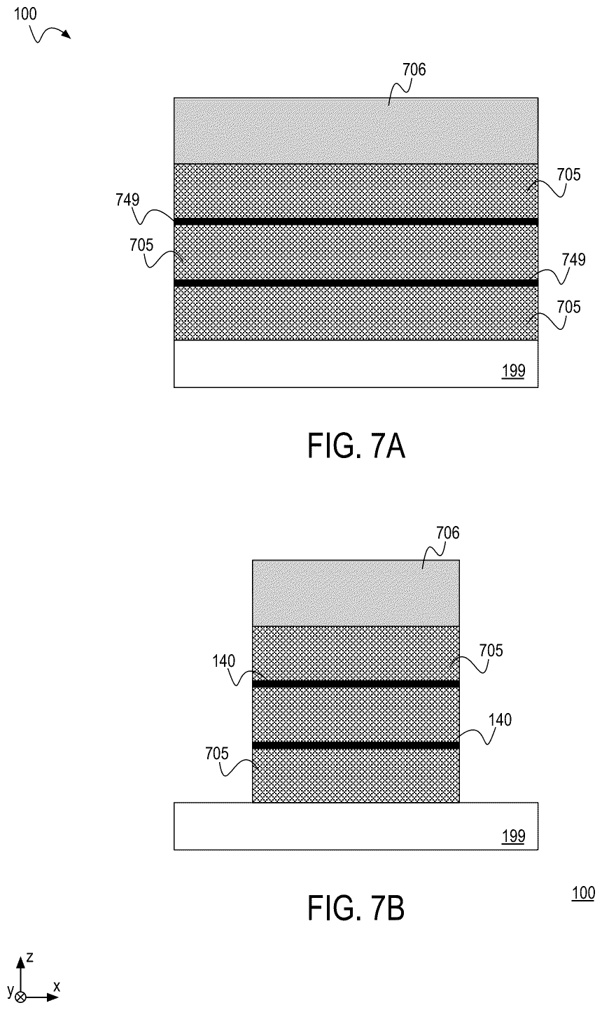

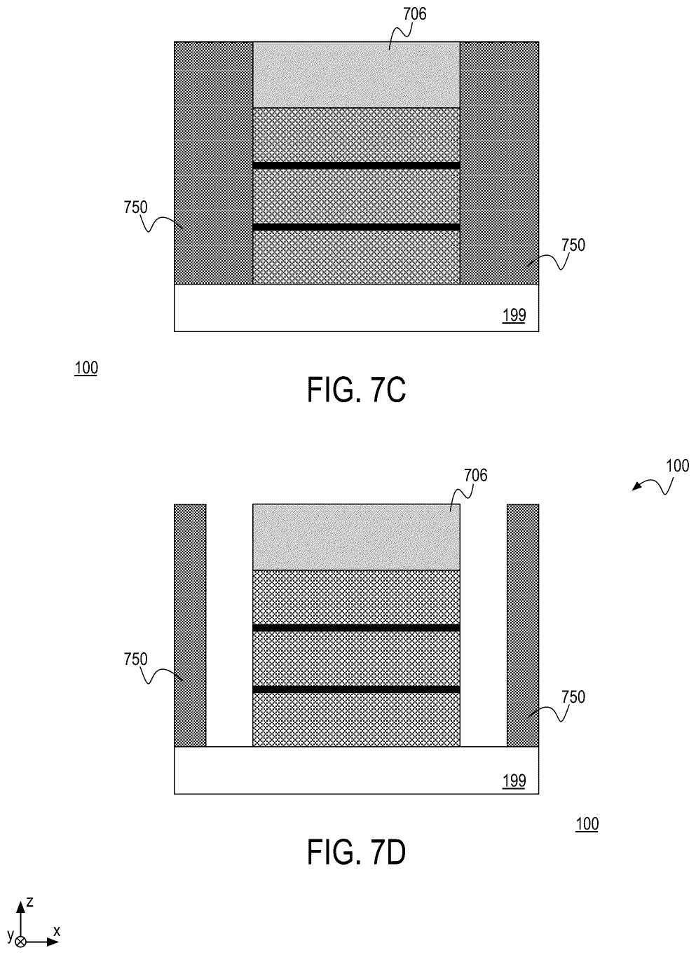

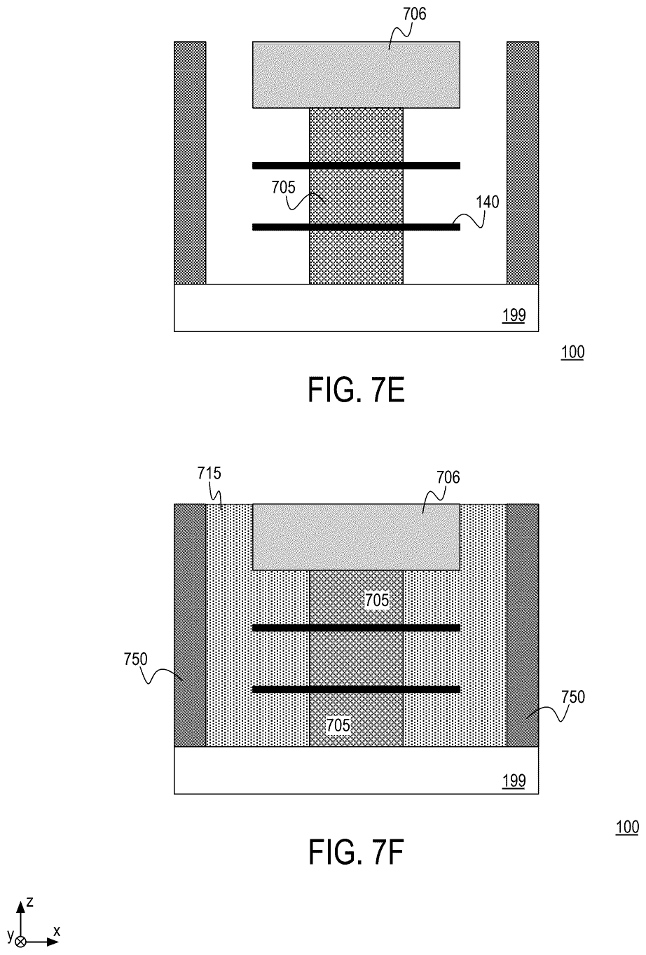

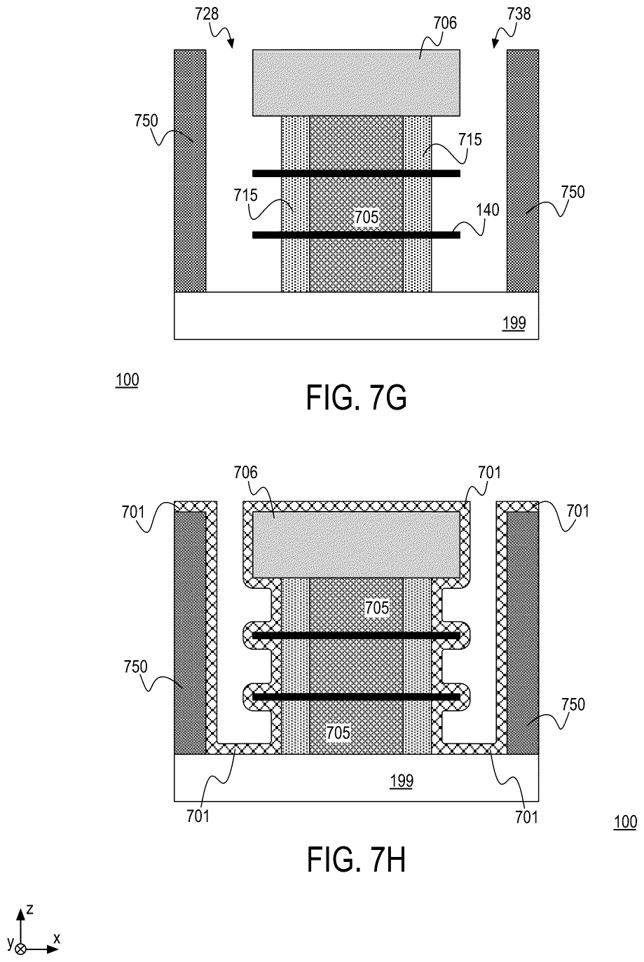

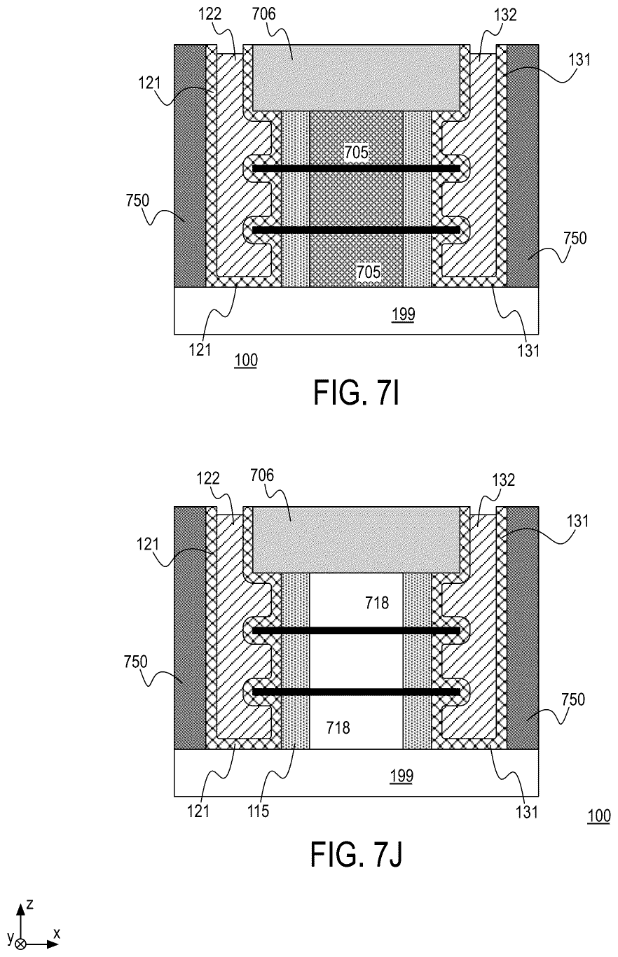

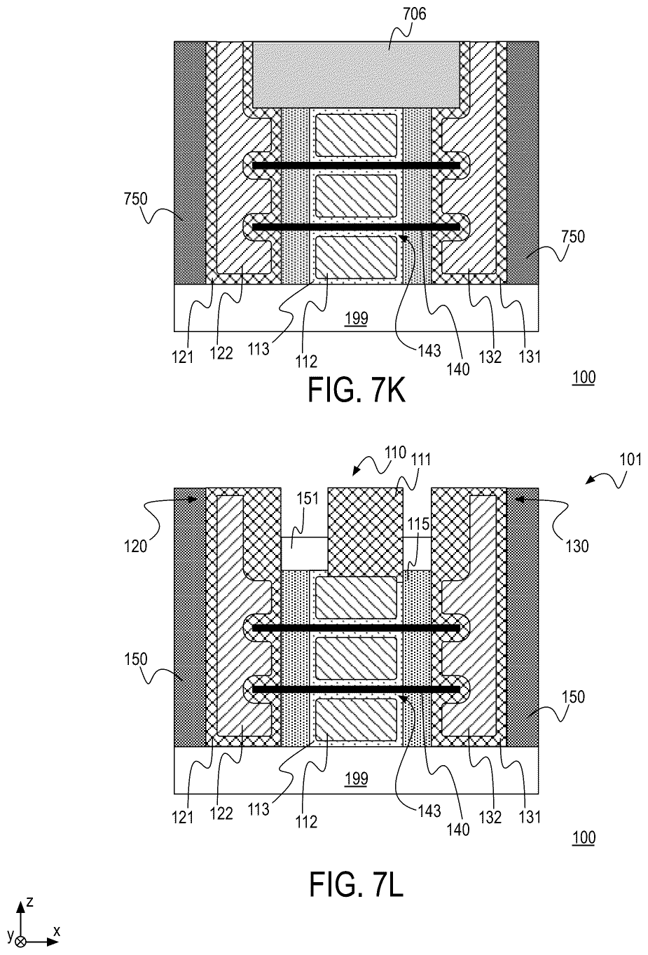

FIGS. 7A, 7B, 7C, 7D, 7E, 7F, 7G, 7H, 7I, 7J, 7K, and 7L illustrate cross-sectional profile views of transistor structure 101 in IC die 100, including conformal liner materials 121, 131 of source and drain terminals 120, 130 contacting nanoribbons 140, at various stages of manufacture, in accordance with some embodiments.

Processes or methods 600 begin at operation 610, where a workpiece is received for processing. For example, any substrate discussed herein may be received for processing. The workpiece may be an IC die or wafer with a device layer already formed. Processes or methods 600 may include forming a transistor structure in a metallization or interconnect layer over a device layer, e.g., at BEOL. The substrate may include an optional dielectric layer, conductive layer (e.g., a back-gate), or etch stop layer.

Processing continues at operation 620, where a multilayer stack is formed. The multilayer stack includes a number of nanoribbons or nanosheets interleaved with sacrificial layers. A hard mask layer may optionally be formed over the stack. A stack of layers may include a single nanoribbon, for example, in back-gated embodiments. The stack may be formed by any suitable means, including deposition techniques, such as atomic layer deposition (ALD), chemical vapor deposition (CVD), including plasma-enhanced CVD, or metal-organic CVD (MOCVD). The nanoribbons may be deposited using a layer transfer technique. For example, a wafer-sized TMD layer may be grown and transferred to the workpiece. In some embodiments, the sacrificial layers are formed using CVD and the nanoribbons/nanosheets are formed using MOCVD. In embodiments forming a transistor structure in an interconnect layer, the multilayer stack may be formed such that nanoribbon ends (e.g., that may protrude or extend into source or drain terminals in a completed transistor structure) in separate trenches (or areas to be trenched) for metallization (e.g., damascene). Such trenches would be separate but adjacent trenches that the channel regions of a completed transistor structure might electrically couple and de-couple.

FIG. 7A illustrates a cross-sectional side view of IC die 100 including a stack of nanoribbons or nanosheets 749 and sacrificial layers 705 over a substrate 199. As shown, the stack includes an optional hardmask layer 706. Nanoribbons or nanosheets 749 may be any materials described herein with respect to nanoribbons 140. Sacrificial layers 705 may be any material that may be removed, e.g., selectively etched, with respect to nanoribbons or nanosheets 749. In some embodiments, sacrificial layers 705 are an oxide, for example, of silicon or aluminum. In some embodiments, hardmask 706 is carbide or nitride, e.g., of silicon. Nanoribbons or nanosheets 749, sacrificial layers 705, and hardmask 706 may be formed using ALD, CVD, MOCVD, PVD, or other suitable means. The stack may be patterned, if necessary, by any suitable means, such as lithography (using optional hardmask 706) and etching means. In some embodiments, nanoribbons/nanosheets 749 are grown to desired dimensions. After patterning, nanosheets 749 may be nanoribbons 140.

Returning to FIG. 6, processing continues at operation 630, where a dielectric or sacrificial material is deposited. The dielectric material may be formed using any suitable means, such as bulk deposition of a dielectric (e.g., silicon nitride) followed by planarization.

FIG. 7B illustrates a cross-sectional side view of IC die 100, e.g., after patterning the stack, for example, using hardmask 706 and lithography means. Nanoribbons 140 are interleaved with sacrificial layers 705.

FIG. 7C illustrates a cross-sectional side view of IC die 100, e.g., after depositing dielectric material 750 at operation 630. In some embodiments, a planarization (e.g., chemical mechanical polishing) operation is performed deposition of dielectric material 750.

Returning to FIG. 6, processing continues at operation 640, where voids are opened in the dielectric material formed at operation 630 to reveal the source and drain ends of the nanoribbons. A selective recess etch may be performed on the sacrificial layers of the stack to expose portions, e.g., of the nanoribbons and other layers. The dielectric material may be selectively removed using any suitable means, such as photolithography and etching. A recess etch may be by selective wet etch or other suitable means

FIG. 7D illustrates a cross-sectional side view of IC die 100, e.g., after opening voids in dielectric material 750 at operation 640 that expose source and drain ends of the stack. In some embodiments, dielectric material 750 is selectively etched. In some such embodiments, a selective etch isotropic etch is performed following an anisotropic etch into dielectric material 750.

FIG. 7E illustrates a cross-sectional side view of IC die 100, e.g., after a recess etch exposes nanoribbons 140. The recess etch may include a selective wet or atomic layer etch (ALE). The etch may define channel region and a gate structure.

Returning to FIG. 6, processing continues, e.g., by repeating operation 630, where a dielectric material is deposited. The dielectric material may be formed using any suitable means. For example, the dielectric material may be bulk deposited followed by planarization. In some embodiments, the dielectric material is a low k dielectric material such as silicon oxide. A void may be opened in the dielectric material, e.g., by using operation 640, to expose the source and drain ends of the stack, and a selective recess etch may be performed on the dielectric material to expose portions of the stack. The dielectric material may be patterned using any suitable means, such as photolithography and etching. The recess etch may be by selective wet etch or ALE. Notably, it may be desirable to expose larger regions of the material layers for landing contact metal. A deeper recess etch may advantageously reveal a larger contact area of the nanoribbons for directly contacting with a conformal liner material.

FIG. 7F illustrates a cross-sectional side view of IC die 100, e.g., after deposition of spacer material 715, for example, using operation 630. In some embodiments, a bulk spacer material is formed and planarization techniques are used to provide a substantially coplanar top surface. Spacer material 715 may be a low-k dielectric material, for example, such as a carbon-doped silicon oxide.

FIG. 7G illustrates a cross-sectional side view of IC die 100, e.g., after opening one or more void(s) in spacer material 715, e.g., voids 728, 738 for source and drain terminals, and after a recess etch to reveal end portions of nanoribbons 140. In some embodiments, a selective etch reveals portions of nanoribbons 140, in some such embodiments, following an anisotropic etch.

Continuing now at operation 650, where a source and drain liner material is formed. The liner material may be conformally deposited over exposed surfaces of the nanoribbons such that the liner material directly contacts (and substantially covers) the previously exposed surfaces. In some embodiments, the liner material is conformally deposited over, and directly contacts, each of the exposed source and drain ends of the nanoribbons. In some such embodiments, the liner material is conformally deposited over, and directly contacts, each of the exposed upper and lower surfaces of the nanoribbons. In some embodiments, e.g., having a back-gated nanoribbon without any exposed lower surface, the liner material is conformally deposited over, and directly contacts, an exposed upper surface of the nanoribbon. In some such embodiments, the liner material is conformally deposited over, and directly contacts, an exposed end of the nanoribbon. In some embodiments, the source and drain liner material are applied using ALD or CVD. The source and drain liner material may include any suitable material, for example, including metal(s) or other materials as have been described herein, e.g., at FIG. 1.

Forming a liner material may require multiple operations, e.g., depositions and/or modifications. In some embodiments, a liner material is deposited with multiple, sequential operations (e.g., ALD). In some embodiments, a liner material is deposited as one material and modified to another material. For example, a 2D material may be deposited and its crystalline structure may be altered after deposition. In some embodiments, a TMD monolayer is deposited in a 2H crystalline phase (e.g., by CVD or ALD) and modified (e.g., by an intercalation or an annealing operation) into a 1T crystalline phase. In some embodiments, a TMD monolayer is deposited with a first composition (e.g., with an atomic layer of a metal between two atomic layers of one chalcogen) and the composition is modified (e.g., with the atomic layer of a metal between an atomic layer of sulfur and an atomic layer of selenium). For example, a TMD monolayer (e.g., of MoS₂ or WS₂) may be deposited, and an exposed layer of sulfur atoms may be removed and replaced by selenium atoms.

The bulk material or fill metal may be formed at operation 670 using any suitable technique(s), such as electroplating followed by planarization processing. Planarization may remove excess materials, including liner material (e.g., metal) between source and drain structures. The bulk material may be any suitably conductive material, such as one or more of cobalt, tungsten, copper, or ruthenium. In some embodiments forming a transistor structure in an interconnect layer, the formation of source and drain liner and bulk material may be concurrent with the metallization of (e.g., damascene) trenches in an interconnect layer. In other similar embodiments, source and drain liner material may later be coupled to, e.g., metallization in an interconnect layer.

FIG. 7H illustrates a cross-sectional side view of IC die 100, e.g., after the deposition of source and drain contact material 701. As shown, source and drain contact material 701 may be substantially conformal to exposed surfaces of nanoribbons 140 and structures adjacent nanoribbons 140, including substrate 199, hardmask 706, and spacer and dielectric materials 715, 750.

FIG. 7I illustrates a cross-sectional side view of IC die 100, e.g., after the bulk material is deposited and planarization processing is deployed to form bulk materials 122, 132 and separate source and drain contact material 701 into discrete structures of source and drain liner material 121, 131. In some embodiments, bulk materials 122, 132 may be recessed with respect to source and drain liner material 121, 131.

Returning to FIG. 6, processing continues at operation, where voids are again opened in sacrificial layers of the stack. In some embodiments, etch techniques are used to selectively expose the sacrificial layers, e.g., an anisotropic etch. The exposed sacrificial layers may then be removed using selective etch techniques.

FIG. 7J illustrates a cross-sectional side view of IC die 100, e.g., after the removal of the remaining portions of sacrificial layers 705 to provide gate structure openings or voids 718. In some embodiments, access to sacrificial layers 705 is provided by patterned openings in dielectric material that are in front of or behind the viewing plane of FIG. 7J. Sacrificial layers 705 are then removed by selective wet etch techniques. As shown, nanoribbons 140 are free standing but supported by spacer 115, source and drain liner material 121, 131, and bulk materials 122, 132.

Returning to FIG. 6, processing continues at operation 660, where a gate dielectric is formed within the voids opened by the removal of the remaining portions of the sacrificial layers. In some embodiments, the gate structure includes a gate dielectric layer and gate electrode. The gate dielectric layer may be formed by conformal deposition using, e.g., ALD. Similarly, the gate electrode (e.g., gate metal) may be formed at operation 670 using deposition techniques including ALD, plating techniques, or the like. In some embodiments, both the gate dielectric layer and the gate electrode are formed using common access openings formed as described. Such gate dielectric layer and gate electrode deposition may then be followed by planarization techniques.

FIG. 7K illustrates a cross-sectional side view of IC die 100, e.g., after the formation of gate structure, which includes gate insulator layer 113 and gate electrode 112 such that gate electrode 112 is separated from nanoribbons 140 by gate insulator layer 113. Gate insulator layer 113 may have a high relative permittivity (i.e., dielectric constant, k). In some high-k gate dielectric embodiments, gate insulator layer 113 is a metal oxide including oxygen and one or more metals, such as, but not limited to, aluminum, hafnium, zirconium, tantalum, or titanium. In some embodiments, gate insulator layer 113 is silicon oxide. Gate electrode 112 may be or include a metal such as but not limited to platinum, nickel, molybdenum, tungsten, palladium, gold, alloys thereof, or nitrides such as titanium nitride, tantalum nitride, tungsten silicon nitride, or others. In some embodiments, gate electrode 112 includes a work function metal and a fill metal. After deposition of gate insulator layer 113 and gate electrode 112, a planarization process is performed to remove excess material.

Returning to FIG. 6, processing may continue with operation 650, where gate, source, and drain contacts may be formed by further, e.g., conformal, deposition of liner material. In some embodiments, after gate formation, an overlying dielectric layer is deposited, and source and drain contact openings are formed in the dielectric layer using lithography and etch techniques. The openings are then filled with liner material, followed by planarization processing.

FIG. 7L illustrates a cross-sectional side view of IC die 100, e.g., after the formation of gate contact 111, source terminal 120, and drain terminal 130. In some embodiments, a bulk dielectric layer (e.g., insulator 151) is formed over a top surface of transistor structure 101 and a resist layer is deposited and patterned on the bulk dielectric layer. Etch techniques are then used to form openings corresponding to gate contact 111 and remaining portions of source terminal 120 and drain terminal 130, and the resist layer is removed. The openings are then filled with liner material or contact metal and planarization techniques are used to form a planar top surface of transistor structure 101. In some embodiments, the metal of gate contact 111 and remaining portions of source terminal 120 and drain terminal 130 are the same as that of source and drain liner material 121, 131, however, other metals may be used.

Processing may continue as is known in the art. Such processing may include forming interconnect features including metallization routings and vias, dicing, packaging, assembly, and so on. The resultant device (e.g., IC die 100) may then be implemented in any suitable form factor.

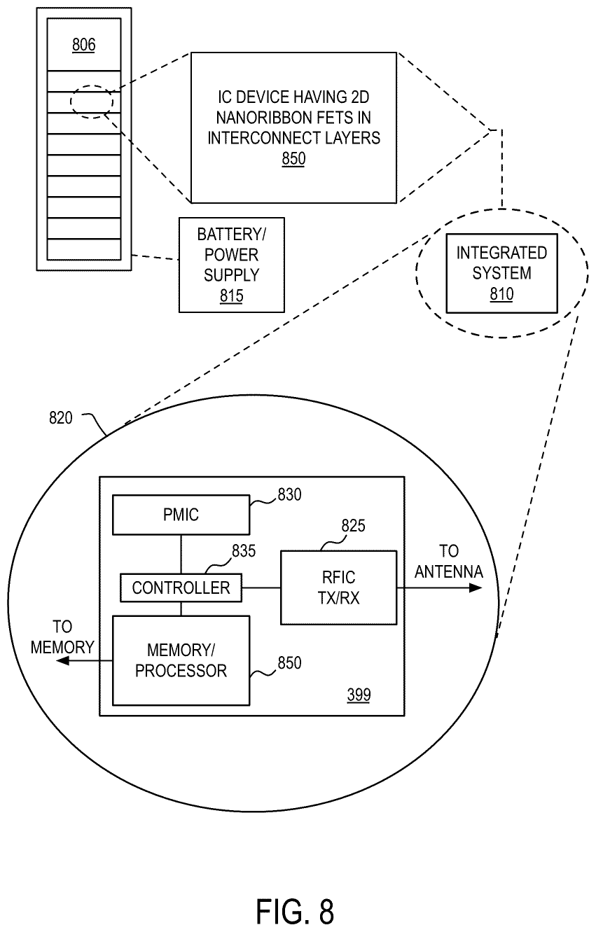

FIG. 8 illustrates a diagram of an example data server machine 806 employing an IC device having 2D nanoribbon channel regions in interconnect layers, in accordance with some embodiments. Server machine 806 may be any commercial server, for example, including any number of high-performance computing platforms disposed within a rack and networked together for electronic data processing, which in the exemplary embodiment includes one or more devices 850 having an IC device with 2D nanoribbon channel regions in interconnect layers.

Server machine 806 includes a battery and/or power supply 815 to provide power to devices 850, and to provide, in some embodiments, power delivery functions such as power regulation. Devices 850 may be deployed as part of a package-level integrated system 810.

Integrated system 810 is further illustrated in the expanded view 820. In the exemplary embodiment, devices 850 (labeled “Memory/Processor”) includes at least one memory chip (e.g., RAM), and/or at least one processor chip (e.g., a microprocessor, a multi-core microprocessor, or graphics processor, or the like) having the characteristics discussed herein. In an embodiment, device 850 is a microprocessor including an SRAM cache memory. As shown, device 850 may include an IC device having 2D nanoribbon channel regions in interconnect layers, as discussed herein. Device 850 may be further coupled to (e.g., communicatively coupled to) a board, an interposer, or host component 399 along with, one or more of a power management IC (PMIC) 830, RF (wireless) IC (RFIC) 825, including a wideband RF (wireless) transmitter and/or receiver (TX/RX) (e.g., including a digital baseband and an analog front end module further includes a power amplifier on a transmit path and a low noise amplifier on a receive path), and a controller 835 thereof. In some embodiments, RFIC 825, PMIC 830, controller 835, and device 850 include an IC device having 2D nanoribbon channel regions in interconnect layers.

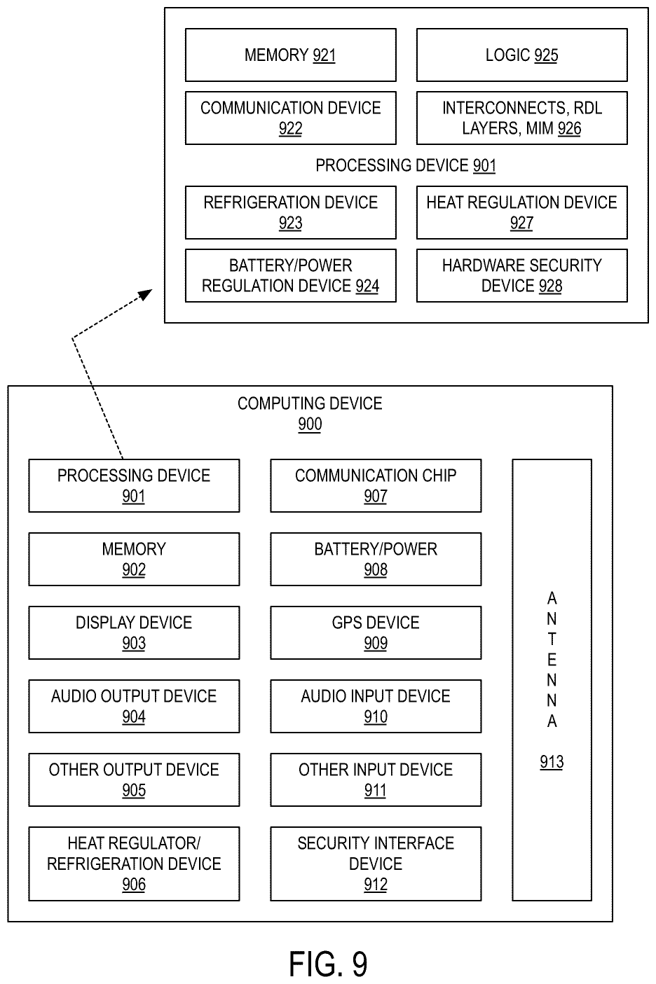

FIG. 9 is a block diagram of an example computing device 900, in accordance with some embodiments. For example, one or more components of computing device 900 may include any of the devices or structures discussed herein. A number of components are illustrated in FIG. 9 as being included in computing device 900, but any one or more of these components may be omitted or duplicated, as suitable for the application. In some embodiments, some or all of the components included in computing device 900 may be attached to one or more printed circuit boards (e.g., a motherboard). In some embodiments, various ones of these components may be fabricated onto a single system-on-a-chip (SoC) die. Additionally, in various embodiments, computing device 900 may not include one or more of the components illustrated in FIG. 9, but computing device 900 may include interface circuitry for coupling to the one or more components. For example, computing device 900 may not include a display device 903, but may include display device interface circuitry (e.g., a connector and driver circuitry) to which display device 903 may be coupled. In another set of examples, computing device 900 may not include an audio output device 904, other output device 905, global positioning system (GPS) device 909, audio input device 910, or other input device 911, but may include audio output device interface circuitry, other output device interface circuitry, GPS device interface circuitry, audio input device interface circuitry, audio input device interface circuitry, to which audio output device 904, other output device 905, GPS device 909, audio input device 910, or other input device 911 may be coupled.

Computing device 900 may include a processing device 901 (e.g., one or more processing devices). As used herein, the term “processing device” or “processor” indicates a device that processes electronic data from registers and/or memory to transform that electronic data into other electronic data that may be stored in registers and/or memory (e.g., SRAM).

Processing device 901 may include a memory 921, a communication device 922, a refrigeration device 923, a battery/power regulation device 924, logic 925, interconnects 926 (i.e., optionally including redistribution layers (RDL) or metal-insulator-metal (MIM) devices), a heat regulation device 927, and a hardware security device 928.

Processing device 901 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 900 may include a memory 902, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 902 includes memory that shares a die with processing device 901. This memory may be used as cache memory and may include embedded dynamic random-access memory (eDRAM) or spin transfer torque magnetic random-access memory (STT-M RAM).

Computing device 900 may include a heat regulation/refrigeration device 906. Heat regulation/refrigeration device 906 may maintain processing device 901 (and/or other components of computing device 900) at a predetermined low temperature during operation.

In some embodiments, computing device 900 may include a communication chip 907 (e.g., one or more communication chips). For example, the communication chip 907 may be configured for managing wireless communications for the transfer of data to and from computing device 900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 907 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 907 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 907 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 907 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 907 may operate in accordance with other wireless protocols in other embodiments. Computing device 900 may include an antenna 913 to facilitate wireless communications and/or to receive other wireless communications (such as AM or FM radio transmissions).

In some embodiments, communication chip 907 may manage wired communications, such as electrical, optical, or any other suitable communication protocols (e.g., the Ethernet). As noted above, communication chip 907 may include multiple communication chips. For instance, a first communication chip 907 may be dedicated to shorter-range wireless communications such as Wi-Fi or Bluetooth, and a second communication chip 907 may be dedicated to longer-range wireless communications such as GPS, EDGE, GPRS, CDMA, WiMAX, LTE, EV-DO, or others. In some embodiments, a first communication chip 907 may be dedicated to wireless communications, and a second communication chip 907 may be dedicated to wired communications.

Computing device 900 may include battery/power circuitry 908. Battery/power circuitry 908 may include one or more energy storage devices (e.g., batteries or capacitors) and/or circuitry for coupling components of computing device 900 to an energy source separate from computing device 900 (e.g., AC line power).

Computing device 900 may include a display device 903 (or corresponding interface circuitry, as discussed above). Display device 903 may include any visual indicators, such as a heads-up display, a computer monitor, a projector, a touchscreen display, a liquid crystal display (LCD), a light-emitting diode display, or a flat panel display, for example.

Computing device 900 may include an audio output device 904 (or corresponding interface circuitry, as discussed above). Audio output device 904 may include any device that generates an audible indicator, such as speakers, headsets, or earbuds, for example.

Computing device 900 may include an audio input device 910 (or corresponding interface circuitry, as discussed above). Audio input device 910 may include any device that generates a signal representative of a sound, such as microphones, microphone arrays, or digital instruments (e.g., instruments having a musical instrument digital interface (MIDI) output).

Computing device 900 may include a GPS device 909 (or corresponding interface circuitry, as discussed above). GPS device 909 may be in communication with a satellite-based system and may receive a location of computing device 900, as known in the art.

Computing device 900 may include other output device 905 (or corresponding interface circuitry, as discussed above). Examples of the other output device 905 may include an audio codec, a video codec, a printer, a wired or wireless transmitter for providing information to other devices, or an additional storage device.

Computing device 900 may include other input device 911 (or corresponding interface circuitry, as discussed above). Examples of the other input device 911 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 900 may include a security interface device 912. Security interface device 912 may include any device that provides security measures for computing device 900 such as intrusion detection, biometric validation, security encode or decode, access list management, malware detection, or spyware detection.

Computing device 900, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-9. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, a transistor structure includes a source terminal and a drain terminal within an IC die, wherein the source and drain terminals each include a liner material and a bulk material, a nanoribbon between and coupled to the source and drain terminals, wherein the nanoribbon includes a transition metal and a chalcogen, and wherein at least a portion of the liner material is between the nanoribbon and the bulk material, a gate electrode material coupled to the nanoribbon, and a gate insulator layer between the nanoribbon and the gate electrode material.

In one or more second embodiments, further to the first embodiments, the liner material directly contacts an end of the nanoribbon.

In one or more third embodiments, further to the first or second embodiments, the liner material directly contacts an upper surface and a lower surface of the nanoribbon.

In one or more fourth embodiments, further to the first through third embodiments, the source and drain terminals are in an interconnect layer of the IC die, the interconnect layer above a device layer.

In one or more fifth embodiments, further to the first through fourth embodiments, the liner material includes at least one of antimony, gold, silver, nickel, titanium, ruthenium, tin, bismuth, aluminum, germanium, tantalum, palladium, platinum, iridium, tungsten, rhodium, or molybdenum.

In one or more sixth embodiments, further to the first through fifth embodiments, the liner material includes graphene.

In one or more seventh embodiments, further to the first through sixth embodiments, the liner material includes the said or a second transition metal and the said or a second chalcogen, and either the liner material is in a metallic crystalline phase or a 1T crystalline phase, or the liner material further includes a dopant.

In one or more eighth embodiments, further to the first through seventh embodiments, the liner material includes one of rhenium, cobalt, or nickel, and one of sulfur or selenium.

In one or more ninth embodiments, further to the first through eighth embodiments, the liner material includes an atomic layer of a metal between an atomic layer of sulfur and an atomic layer of selenium.

In one or more tenth embodiments, further to the first through ninth embodiments, the gate insulator layer is over a layer of the gate electrode material, the nanoribbon is over the gate insulator layer, the source and drain terminals are over the nanoribbon, and the liner material directly contacts an upper surface of the nanoribbon.

In one or more eleventh embodiments, further to the first through tenth embodiments, the nanoribbon is one of a plurality of nanoribbons between and directly contacting the source and drain terminals, individual ones of the nanoribbons include a channel region including a transition metal and a chalcogen, and the liner material directly contacts an end of each of the plurality of nanoribbons.

In one or more twelfth embodiments, further to the first through eleventh embodiments, the liner material directly contacts an upper surface and a lower surface of each of the plurality of nanoribbons.

In one or more thirteenth embodiments, an IC device includes an IC die including a transistor, the transistor including a source terminal and a drain terminal within the IC die, wherein the source and drain terminals include a liner material and a bulk material, a plurality of nanoribbons between and coupled to the source and drain terminals, wherein individual ones of the nanoribbons include a transition metal and a chalcogen, and wherein at least a portion of the liner material is between individual ones of the nanoribbons and the bulk material, a gate electrode material between and coupled to individual ones of the nanoribbons, and a gate insulator layer between individual ones of the nanoribbons and the gate electrode material, and a power supply coupled to the IC die.

In one or more fourteenth embodiments, further to the thirteenth embodiments, the liner material directly contacts a plurality of ends of corresponding ones of the nanoribbons.

In one or more fifteenth embodiments, further to the thirteenth or fourteenth embodiments, the liner material directly contacts a plurality of upper and lower surfaces of corresponding ones of the nanoribbons.

In one or more sixteenth embodiments, a method includes receiving a workpiece including a substrate, forming a stack of interleaved nanoribbons and sacrificial layers over the substrate, depositing a dielectric or sacrificial material, opening voids in the dielectric or sacrificial material, forming a gate dielectric in a void between nanoribbons, conformally depositing a liner material coupled to the nanoribbons, and filling a metal over the liner material or the gate dielectric.

In one or more seventeenth embodiments, further to the sixteenth embodiments, conformally depositing the liner material directly contacts the liner material to a plurality of ends of corresponding ones of the nanoribbons.

In one or more eighteenth embodiments, further to the sixteenth or seventeenth embodiments, conformally depositing the liner material directly contacts the liner material to a plurality of upper and lower surfaces of corresponding ones of the nanoribbons.

In one or more nineteenth embodiments, further to the sixteenth through eighteenth embodiments, conformally depositing the liner material includes a chemical vapor deposition or an atomic layer deposition.

In one or more twentieth embodiments, further to the sixteenth through nineteenth embodiments, the substrate is over a device layer.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. A transistor structure, comprising:
a source terminal and a drain terminal within an integrated circuit (IC) die, wherein the source and drain terminals each comprise a liner material and a bulk material;
a nanoribbon between and coupled to the source and drain terminals, wherein the nanoribbon comprises a transition metal and a chalcogen, and wherein at least a portion of the liner material is between the nanoribbon and the bulk material;
a gate electrode material coupled to the nanoribbon; and
a gate insulator layer between the nanoribbon and the gate electrode material.

2. The transistor structure of claim 1, wherein the liner material directly contacts an end of the nanoribbon.

3. The transistor structure of claim 2, wherein the liner material directly contacts an upper surface and a lower surface of the nanoribbon.

4. The transistor structure of claim 1, wherein the source and drain terminals are in an interconnect layer of the IC die, the interconnect layer above a device layer.

5. The transistor structure of claim 1, wherein the liner material comprises at least one of antimony, gold, silver, nickel, titanium, ruthenium, tin, bismuth, aluminum, germanium, tantalum, palladium, platinum, iridium, tungsten, rhodium, or molybdenum.

6. The transistor structure of claim 1, wherein the liner material comprises graphene.

7. The transistor structure of claim 1, wherein the liner material comprises the said or a second transition metal and the said or a second chalcogen, and either the liner material is in a metallic crystalline phase or a 1T crystalline phase, or the liner material further comprises a dopant.

8. The transistor structure of claim 1, wherein the liner material comprises one of rhenium, cobalt, or nickel, and one of sulfur or selenium.

9. The transistor structure of claim 1, wherein the liner material comprises an atomic layer of a metal between an atomic layer of sulfur and an atomic layer of selenium.

10. The transistor structure of claim 1, wherein:
the gate insulator layer is over a layer of the gate electrode material;
the nanoribbon is over the gate insulator layer;
the source and drain terminals are over the nanoribbon; and
the liner material directly contacts an upper surface of the nanoribbon.

11. The transistor structure of claim 1, wherein the nanoribbon is one of a plurality of nanoribbons between and directly contacting the source and drain terminals, individual ones of the nanoribbons comprise a channel region comprising a transition metal and a chalcogen, and the liner material directly contacts an end of each of the plurality of nanoribbons.

12. The transistor structure of claim 11, wherein the liner material directly contacts an upper surface and a lower surface of each of the plurality of nanoribbons.

13. An integrated circuit (IC) device, comprising:
an IC die comprising a transistor, the transistor comprising:
a source terminal and a drain terminal within the IC die, wherein the source and drain terminals comprise a liner material and a bulk material;
a plurality of nanoribbons between and coupled to the source and drain terminals, wherein individual ones of the nanoribbons comprise a transition metal and a chalcogen, and wherein at least a portion of the liner material is between individual ones of the nanoribbons and the bulk material;
a gate electrode material between and coupled to individual ones of the nanoribbons; and
a gate insulator layer between individual ones of the nanoribbons and the gate electrode material; and
a power supply coupled to the IC die.

14. The IC device of claim 13, wherein the liner material directly contacts a plurality of ends of corresponding ones of the nanoribbons.

15. The IC device of claim 14, wherein the liner material directly contacts a plurality of upper and lower surfaces of corresponding ones of the nanoribbons.

16. A method, comprising:
receiving a workpiece comprising a substrate;
forming a stack of interleaved nanoribbons and sacrificial layers over the substrate;
depositing a dielectric or sacrificial material;
opening voids in the dielectric or sacrificial material;
forming a gate dielectric in a void between nanoribbons;
conformally depositing a liner material coupled to the nanoribbons; and
filling a metal over the liner material or the gate dielectric.

17. The method of claim 16, wherein conformally depositing the liner material directly contacts the liner material to a plurality of ends of corresponding ones of the nanoribbons.

18. The method of claim 17, wherein conformally depositing the liner material directly contacts the liner material to a plurality of upper and lower surfaces of corresponding ones of the nanoribbons.

19. The method of claim 16, wherein conformally depositing the liner material comprises a chemical vapor deposition or an atomic layer deposition.

20. The method of claim 16, wherein the substrate is over a device layer.
